(19) United States
(12) Patent Application Publication
(10) Pub. No.: US 2007/0248891 A1
(43) Pub. Date: Oct. 25, 2007

(54) Method of manufacturing field emission display (FED) using half tone photomask

(76) Inventor: In-Taek Han, Seoul (KR)

Correspondence Address: Robert E. Bushnell, Suite 300, 1522 K Street, N.W., Washington, DC, 20005, US

(21) Appl. No.: 11/540,639

(22) Filed: Oct. 2, 2006

(30) Foreign Application Priority Data
Apr. 19, 2006 (KR) 10-2006-0035365

(51) Int. Cl. G03F 1/00

(52) U.S. Cl. 430/5

(57) ABSTRACT

A method of manufacturing a Field Emission Display (FED) having a double gate structure using a half tone photomask includes sequentially forming a cathode material layer, a resistance material layer, and a photoresist on a substrate, arranging a half tone photomask on the photoresist, the half tone photomask having a first pattern that shields light and a second pattern that partially transmits light formed in respective predetermined shapes, exposing the photoresist to light to develop it, forming a resistance layer and a cathode electrode by sequentially etching the resistance material layer and the cathode material layer exposed through the developed photoresist, etching the developed photoresist until the resistance layer located on an upper part of a pad region of the cathode electrode is exposed, exposing the pad region of the cathode electrode by etching the resistance layer exposed through the etched photoresist, and removing the photoresist.

### CLAIM OF PRIORITY

This application makes reference to, incorporates the same herein, and claims all benefits accruing under 35 U.S.C.§119 from an application for METHOD OF MANUFACTURING FIELD EMISSION DISPLAY USING HALF TONE PHOTOMASK earlier filed in the Korean Intellectual Property Office on the 19^{th} of Apr. 2006 and there duly assigned Serial No. 10-2006-0035365.

### BACKGROUND OF THE INVENTION

1. Field of the Invention

The present invention relates to a method of manufacturing a Field Emission Display (FED) using a half tone photomask, and more particularly, to a method of manufacturing a FED which has a reduced number of manufacturing processes and reduced costs due to the use of a half tone photomask.

2. Description of the Related Art

Major application fields of displays which are a main part of information transfer media are monitors of personal computers and television receivers. Displays can be classified into Cathode Ray Tubes (CRTs) that use the emission of high speed thermal electrons and flat panel displays which have rapidly developed in recent years. The flat panel displays include Liquid Crystal Displays (LCDs), Plasma Display Panels (PDPs), and Field Emission Displays (FEDs).

An FED emits light using collisions of electrons emitted from emitters with a phosphor material formed on an anode electrode, wherein the electrons are emitted from the emitters when a strong electric field is formed between emitters arranged a predetermined distance apart from each other on a cathode electrode and a gate electrode. The FED has received much attention as a next generation display together with LCDs and PDPs since it can be manufactured in thin sizes having an overall thickness of a few centimeters, has a wide viewing angle, and has low power consumption and low manufacturing costs.

In an FED having a double gate structure, a cathode electrode, a resistance layer, a first insulating layer, a first gate electrode, a second insulating layer, and a second gate electrode are sequentially formed on a substrate. A first insulating layer hole that exposes the resistance layer is formed in the first insulating layer, and a second insulating layer hole that is connected to the first insulating layer hole is formed in the second gate electrode. An emitter that emits electrons is formed on an upper surface of the resistance layer exposed through the first insulating layer hole. In the above structure, the resistance layer ensures uniform intensity of current emitted from the emitter. The first gate electrode extracts electrons from the emitter and the second gate electrode focuses the electrons emitted from the emitter.

In another FED having a double gate structure, a resistance layer is formed under a cathode electrode, and an emitter is on an upper surface of the cathode electrode exposed through a first insulating layer hole. A portion of the cathode electrode on which the emitter is formed is formed in an island shape, and the portion where the emitter is formed is surrounded by a trench that is formed to expose the resistance layer.

In order to manufacture such FEDs having the double gate structure, at least six sheets of photomask are required. More specifically, the six photomasks are required for forming the cathode electrode, the resistance layer, the first gate electrode, the second gate electrode, the first insulating layer hole, and the second insulating layer hole. Therefore, the manufacturing process is complex due to the increased number of times that the exposing and aligning operations are performed, thereby increasing manufacturing costs.

### SUMMARY OF THE INVENTION

The present invention provides a method of manufacturing a Field Emission Display (FED) which has a reduced number of manufacturing processes and reduced costs due to the formation of a cathode electrode and a resistance layer using one half tone photomask.

According to one aspect of the present invention, a method of manufacturing a Field Emission Display (FED) is provided, the method including: sequentially forming a cathode material layer, a resistance material layer, and a photoresist on a substrate; arranging a half tone photomask on the photoresist, the half tone photomask having a first pattern that shields light and a second pattern that partially transmits light arranged in respective predetermined shapes; exposing the photoresist to light to develop it; forming a resistance layer and a cathode electrode by sequentially etching the resistance material layer and the cathode material layer exposed through the developed photoresist; etching the developed photoresist until the resistance layer located on an upper part of a pad region of the cathode electrode is exposed; exposing the pad region of the cathode electrode by etching the resistance layer exposed through the etched photoresist; and removing the photoresist.

Forming the photoresist preferably includes forming a positive photoresist.

The first pattern is preferably formed corresponding to active regions of the cathode electrode, and the second pattern is preferably formed corresponding to the pad region of the cathode electrode electrically connected to an external power source. The first and second patterns are preferably formed on a transparent substrate. The second pattern is preferably formed to have a light transmittance in a range of 25 to 80%.

The photoresist located on an upper part of the pad region of the cathode electrode is preferably exposed and developed to a predetermined depth due to light transmitted through the second pattern. The developed photoresist is preferably etched using a plasma etching method. The plasma etching method preferably includes Reactive Ion Etching (RIE).

According to another aspect of the present invention, a method of manufacturing a Field Emission Display (FED) is provided, the method including: sequentially forming a resistance material layer, a cathode material layer, and a photoresist on a substrate; arranging a half tone photomask on the photoresist, the half tone photomask having a first pattern that shields light and a second pattern that partially transmits light arranged in respective predetermined shapes; exposing the photoresist to light to develop it; forming a cathode electrode and a resistance layer by sequentially etching the cathode material layer and the resistance material layer exposed through the developed photoresist; etching the developed photoresist until a region that surrounds emitter forming portions of the cathode electrode is exposed; exposing the resistance layer by etching the cathode electrode exposed through the etched photoresist; and removing the photoresist.

Forming the photoresist preferably includes forming a positive photoresist.

The first pattern is preferably formed corresponding to the cathode electrode, and the second pattern is preferably formed corresponding to the region that surrounds the emitter forming portion. The first and second patterns are preferably formed on a transparent substrate. The second pattern is preferably formed to have a light transmittance in the range of 25 to 80%.

The photoresist located on an upper part of the region that surrounds the emitter forming portion is preferably exposed and developed to a predetermined depth due to light transmitted through the second pattern. The developed photoresist is preferably etched using a plasma etching method. The plasma etching method preferably includes Reactive Ion Etching (RIE).

### BRIEF DESCRIPTION OF THE DRAWINGS

A more complete appreciation of the present invention and many of the attendant advantages thereof, will be readily apparent as the present invention becomes better understood by reference to the following detailed description when considered in conjunction with the accompanying drawings in which like reference symbols indicate the same or similar components, wherein:

FIGS. 1A and 1B are cross-sectional views of Field Emission Displays (FED) having a double gate structure.

FIGS. 2A through 10B are views for explaining a method of manufacturing an FED according to an embodiment of the present invention; and

FIGS. 11A through 19B are views for explaining another method of manufacturing an FED according to an embodiment of the present invention.

### DETAILED DESCRIPTION OF THE INVENTION

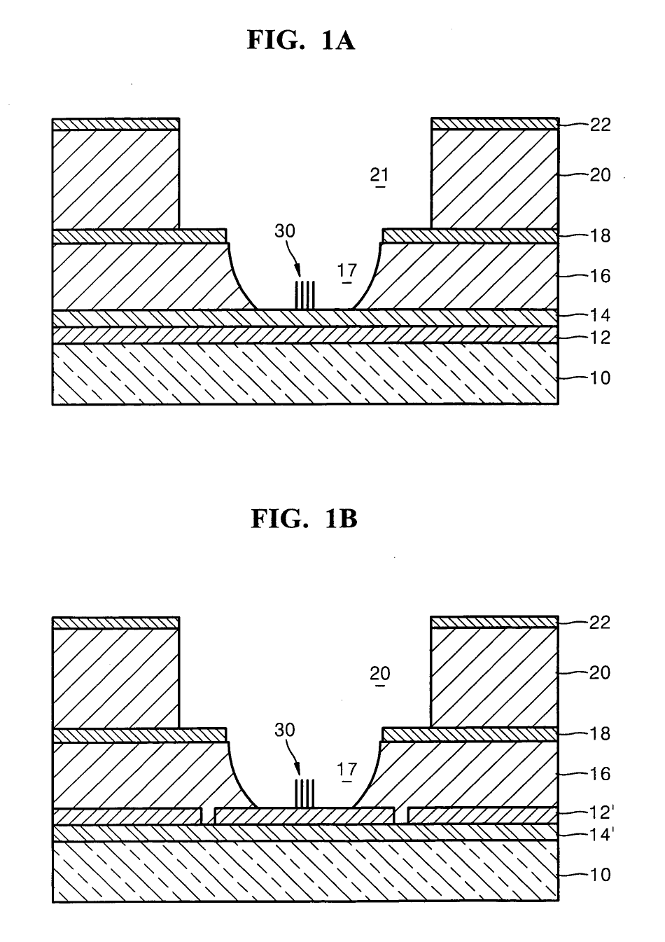

FIGS. 1A and 1B are cross-sectional views of an Field Emission Display (FED) having a double gate structure. Referring to FIG. 1A, the FED has a structure in which a cathode electrode 12, a resistance layer 14, a first insulating layer 16, a first gate electrode 18, a second insulating layer 20, and a second gate electrode 22 are sequentially formed on a substrate 10. A first insulating layer hole 17 that exposes the resistance layer 14 is formed in the first insulating layer 16, and a second insulating layer hole 21 that is connected to the first insulating layer hole 17 is formed in the second gate electrode 22. An emitter 30 that emits electrons is formed on an upper surface of the resistance layer 14 exposed through the first insulating layer hole 17. In the above structure, the resistance layer 14 ensures uniform intensity of current emitted from the emitter 30. The first gate electrode 18 extracts electrons from the emitter 30 and the second gate electrode 22 focuses the electrons emitted from the emitter 30.

FIG. 1B is a cross-sectional view of another FED having a double gate structure. Referring to FIG. 1B, a resistance layer 14′ is formed under a cathode electrode 12′, and an emitter 30 is on an upper surface of the cathode electrode 12′ exposed through a first insulating layer hole 17. A portion of the cathode electrode 12′ on which the emitter 30 is formed is formed in an island shape, and the portion where the emitter 30 is formed is surrounded by a trench that is formed to expose the resistance layer 14′.

In order to manufacture such FEDs having the double gate structure, at least six sheets of photomask are required. More specifically, the six photomasks are required for forming the cathode electrode 12 or 12′, the resistance layer 14 or 14′, the first gate electrode 18, the second gate electrode 22, the first insulating layer hole 17, and the second insulating layer hole 21. Therefore, the manufacturing process is complex due to the increased number of times exposing and aligning operations are performed, thereby increasing manufacturing costs.

The present invention is related to a method of manufacturing a cathode electrode and a resistance layer using one half tone photomask. According to the present invention, the numbers of photomasks required for manufacturing a Field Emission Display (FED) device can be reduced.

The present invention will now be described more fully with reference to the accompanying drawings in which exemplary embodiments of the present invention are shown. In the drawings, the thicknesses of layers and regions are exaggerated for clarity.

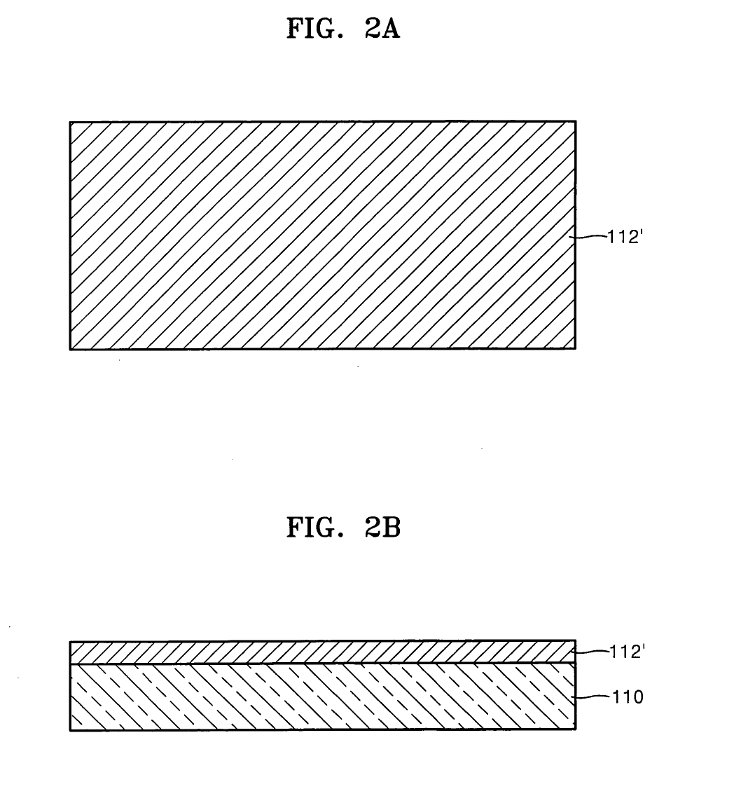

FIGS. 2A through 10B are views for explaining a method of manufacturing an FED device according to an embodiment of the present invention.

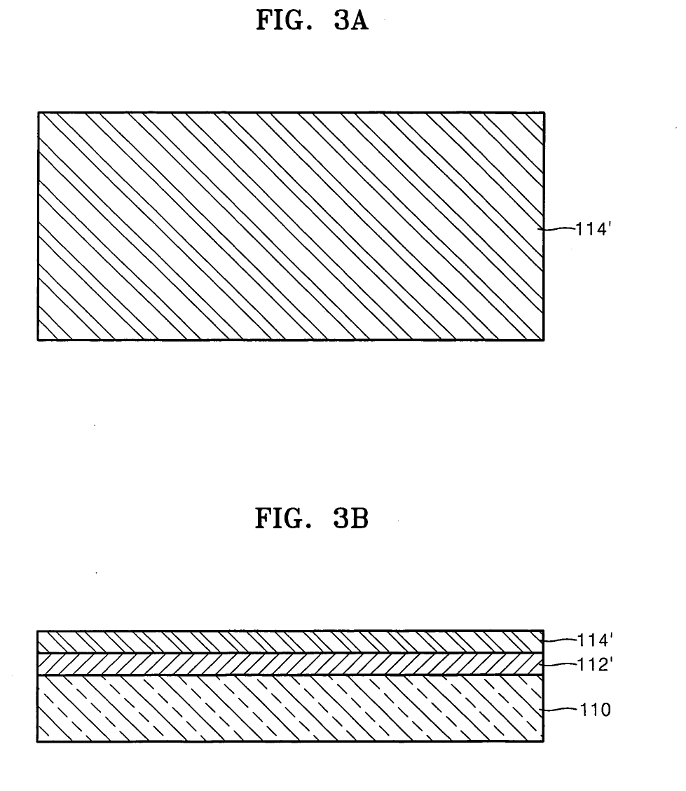

FIGS. 2A and 2B are respectively a plan view and a cross-sectional view of a cathode material layer 112′ formed on a substrate 110. Referring to FIGS. 2A and 2B, the cathode material layer 112′ is formed to a predetermined thickness on the substrate 110. The substrate 110 generally can be a transparent substrate, and the cathode material layer 112′ can be formed of a transparent conductive material, such as Indium Tin Oxide (ITO). Referring to FIGS. 3A and 3B, a resistance material layer 114′ is formed on the cathode material layer 112′.

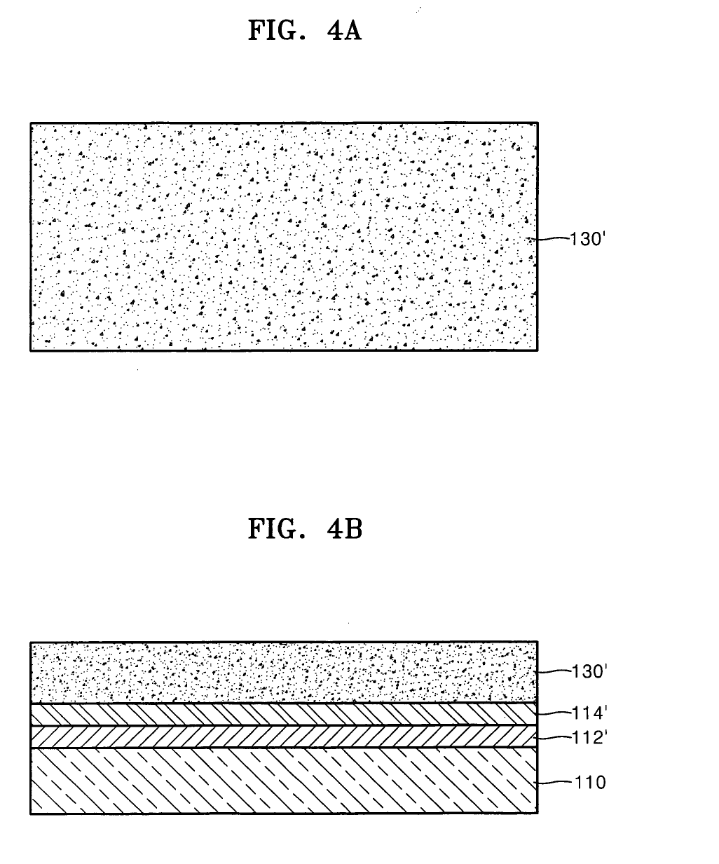

Referring to FIGS. 4A and 4B, a photoresist 130′ is coated to a predetermined thickness on the resistance material layer 114′. The photoresist 130′ can be a positive photoresist in which an exposed portion of the photoresist is removed by a developing solution.

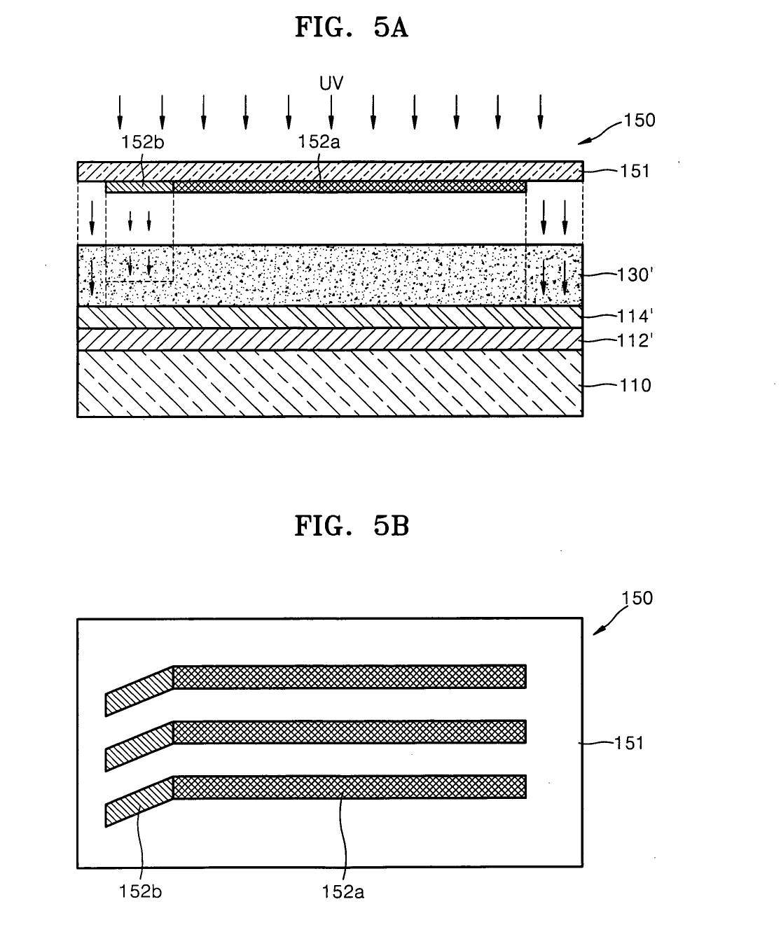

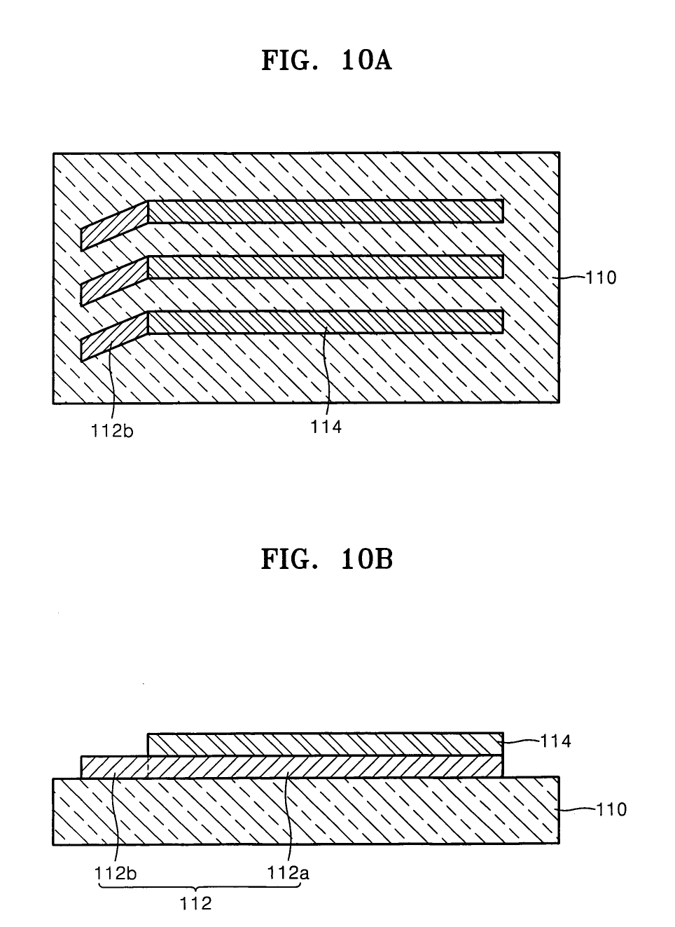

Referring to FIG. 5A, after providing a half tone photomask 150 on the photoresist 130′, the photoresist 130′ is partially exposed and developed. FIG. 5B is a plan view of the half tone photomask 150. Referring to FIG. 5B, the half tone photomask 150 consists of a transparent substrate 151 and a plurality of first and second patterns 152a and 152b formed in a predetermined shape on the transparent substrate 151. The first pattern 152a is formed to shield incident light, and the second pattern 152b is formed to partially transmit the incident light. The second pattern 152b can have a light transmittance in a range of 25 to 80%. In the present embodiment, the first pattern 152a is formed corresponding to active regions 112a of a cathode electrode 112 (see FIG. 10B) where emitters, which will be described later, are formed. The second pattern 152b is formed corresponding to a pad region 112b of the cathode electrode 112 electrically connected to an external power source.

After providing the half tone photomask 150 on the photoresist 130′, ultraviolet rays are radiated from above the half tone photomask 150. In this process, the photoresist 130′ in the light transmitting region can be completely exposed since the ultraviolet rays reach the bottom of the photoresist 130′ in the light transmitting region located under a transparent portion of the half tone photomask 150, without almost any loss of the ultraviolet rays. The photoresist 130′ in the light shielding region located under the first pattern 152a is not exposed since the ultraviolet rays do not reach the photoresist 130′. The photoresist 130′ in the partial light transmitting region located under the second pattern 152b can be exposed to a predetermined depth according to the intensity of the ultraviolet rays reaching the photoresist 130′. If the transmittance of the second pattern 152b is, for example, approximately 50%, the photoresist 130′ in the partial light transmitting region can be exposed to a depth corresponding to the half of the thickness of the photoresist 130′.

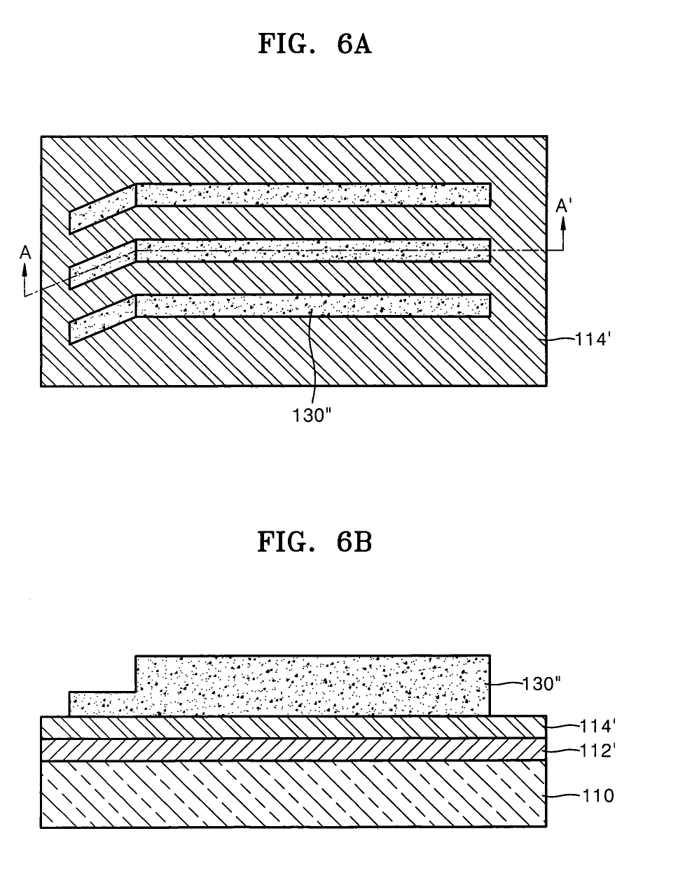

When the exposed photoresist 130′ is developed, a developed photoresist 130″ having a shape as shown in FIGS. 6A and 6B can be obtained. FIG. 6B is a cross-sectional view taken along the line A-A′ of FIG. 6A. More specifically, the photoresist 130′ in the light transmitting 1S region is removed by a developing solution and the resistance material layer 114′ located thereunder is exposed. The photoresist 130′ in the light shielding region formed by the first pattern 152a is not removed by the developing solution since the photoresist 130′ is not exposed. The partially exposed portion of the photoresist 130′ in the partial light transmitting region formed by the second pattern 152b is removed by the developing solution. Accordingly, as shown in FIG. 6B, the developed photoresist 130″ has a step difference between the light shielding region and the partial light transmitting region.

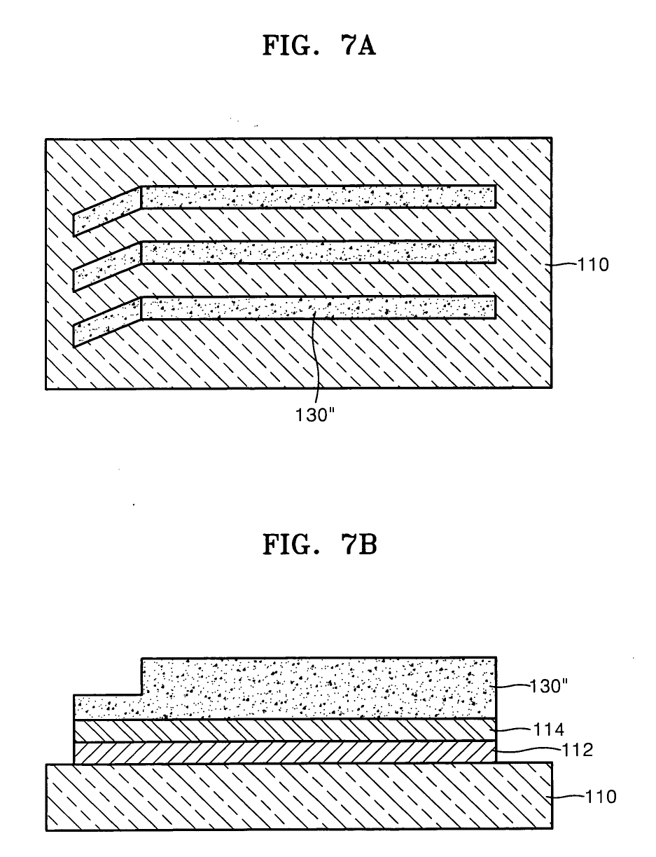

Referring to FIGS. 7A and 7B, a resistance layer 114 and a cathode electrode 112 are formed by sequentially etching the exposed resistance material layer 114′ and the cathode material layer 112′ using the developed photoresist 130″.

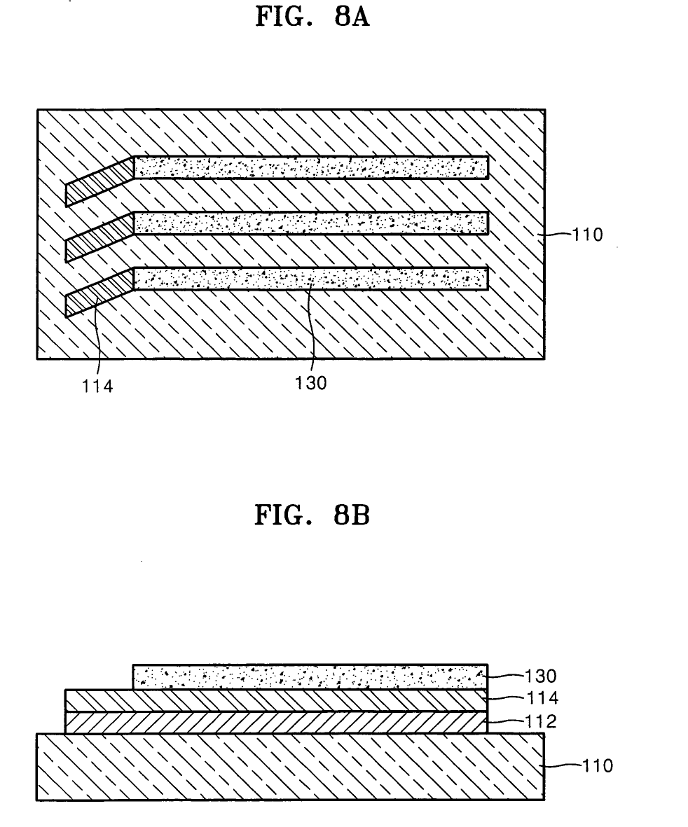

Referring to FIGS. 8A and 8B, a portion of the resistance layer 114 is exposed by etching the exposed photoresist 130″. More specifically, the developed photoresist 130″ is etched using a plasma etching method. The plasma etching method can include Reactive Ion Etching (RIE). In this process, the height of the developed photoresist 130″ is gradually reduced by etching an upper surface of the developed photoresist 130″. The etching of the developed photoresist 130″ is continued until the developed photoresist 130″ in the partial light transmitting region is completely removed and the resistance layer 114, that is, the resistance layer located on an upper part of a pad region 112b of a cathode electrode 112 (see FIG. 10B) which will be described later, located under the developed photoresist 130″ is exposed. As a result, a photoresist 130 in the light shielding region remains at a predetermined height on the resistance layer 114.

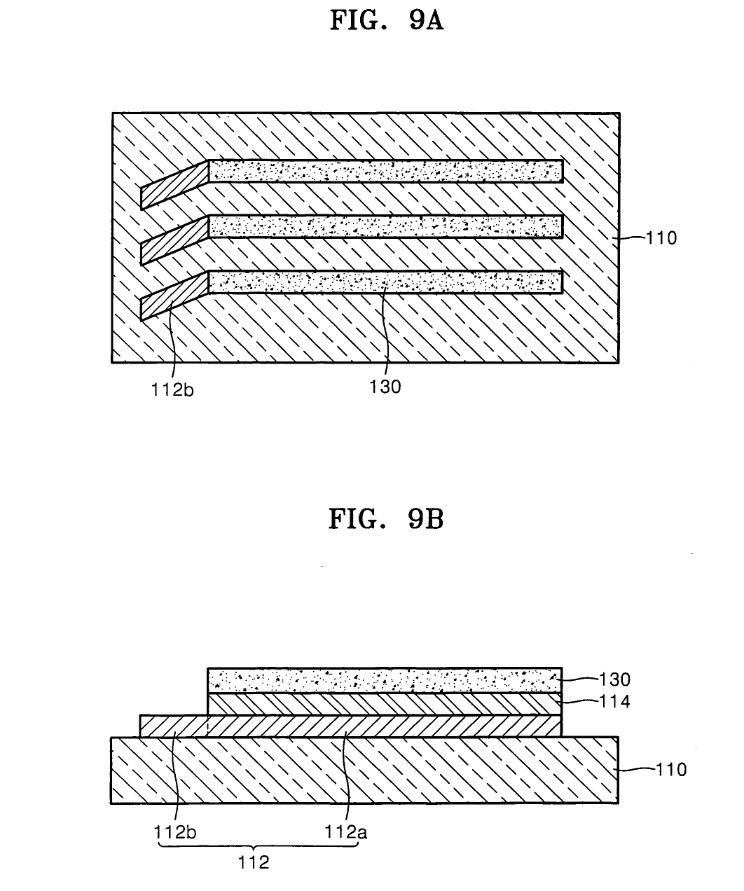

Referring to FIGS. 9A and 9B, the pad region 112b of the cathode electrode 112 under the resistance layer 114 is exposed by etching the exposed resistance layer 114 using the photoresist 130 as an etch mask. An active region 112a of the cathode electrode 112 remains covered by the resistance layer 114. Referring to FIGS. 10A and 10B, the photoresist 130 remaining on the resistance layer 114 is removed.

Although not shown, the manufacture of an FED is completed when a first insulating layer, a first gate electrode, a second insulating layer, and a second gate electrode are formed on the cathode electrode 112, the resistance layer 114 is formed on the substrate 110 and emitters are formed in the active regions of the cathode electrode 112. In the FED having a double gate structure, the resistance layer 114 ensures uniform intensity of currents emitted from the emitter.

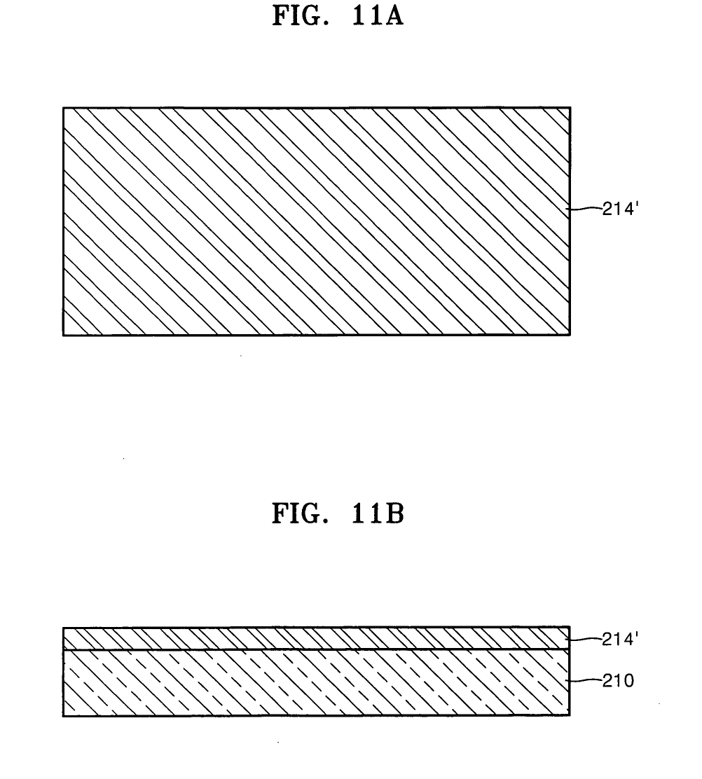

FIGS. 11A through 19B are views for explaining another method of manufacturing an FED according to an embodiment of the present invention.

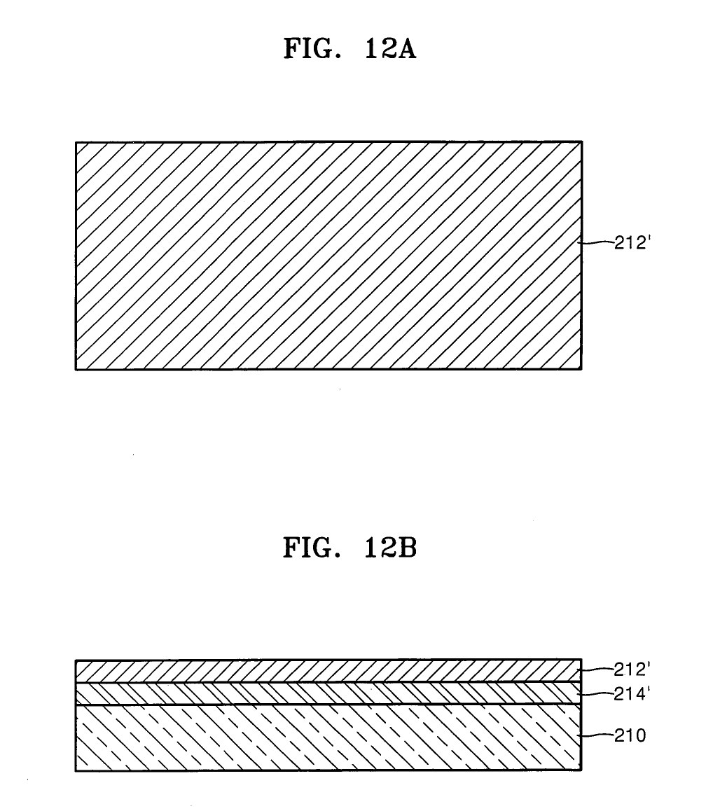

FIGS. 11A and 11B are respectively a plan view and a cross-sectional view of a resistance material layer 214′ formed on a substrate 210. Referring to FIGS. 11A and 11B, the resistance material layer 214′ is formed to a predetermined thickness on the substrate 210. Referring to FIGS. 12A and 12B, a cathode material layer 212′ having a predetermined thickness is formed on the resistance material layer 214′.

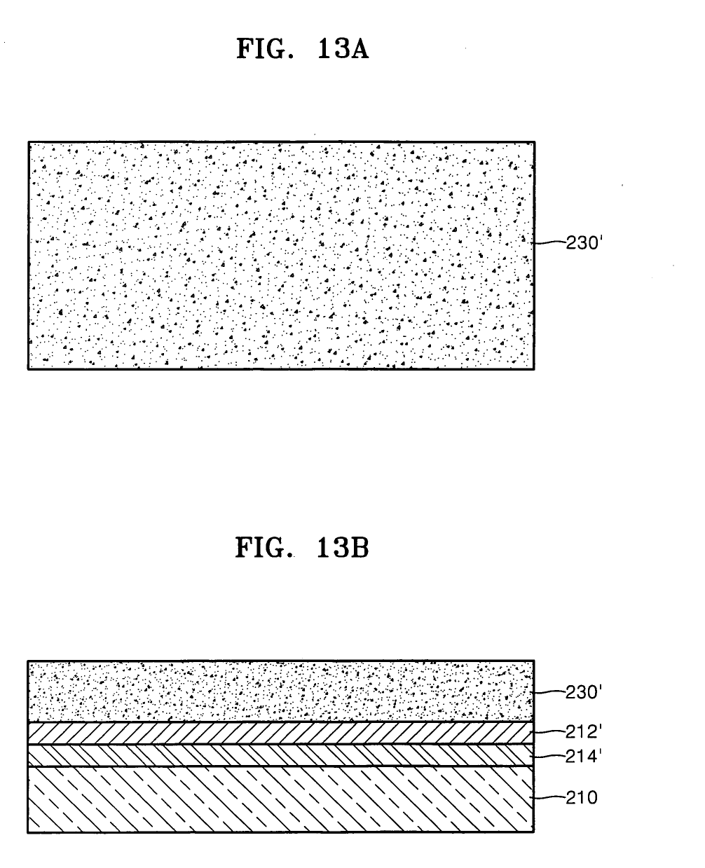

Referring to FIGS. 13A and 13B, a photoresist 230′ is coated to a predetermined thickness on the cathode material layer 212′. The photoresist 230′ can be a positive photoresist.

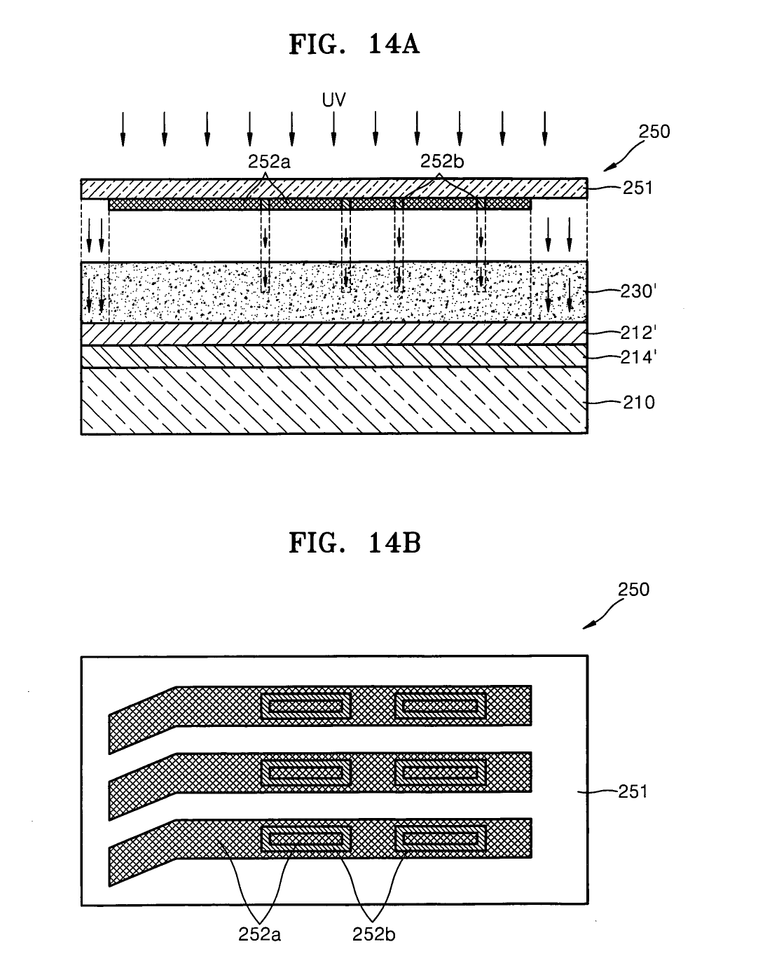

Referring to FIG. 14A, after providing a half tone photomask 250 on the photoresist 230′, the photoresist 230′ is exposed and developed. FIG. 14B is a plan view of the half tone photomask 250. Referring to FIG. 14B, the half tone photomask 250 consists of a transparent substrate 251 and a plurality of first and second patterns 252a and 252b formed in a predetermined shape on the transparent substrate 251. The first pattern 252a is formed to shield incident light, and the second pattern 252b is formed to partially transmit the incident light. The second pattern 252b can have a light transmittance in a range of 25 to 80%. In the present embodiment, the first pattern 252a is formed corresponding to a cathode electrode 212 (see FIG. 119B) where emitters, which will be described later, are formed. The second pattern 252b is formed corresponding to a region that surrounds an emitter forming portion 212a′ of the cathode electrode 212.

After providing the half tone photomask 250 on the photoresist 230′, ultraviolet rays are radiated from above the half tone photomask 250. In this process, the photoresist 230′ in the light transmitting region located under a transparent portion of the half tone photomask 250 can be completely exposed. The photoresist 230′ in the light shielding region is not exposed. The photoresist 230′ in the partial light transmitting region located under the second pattern 252b can be exposed to a predetermined depth according to the intensity of the ultraviolet rays reaching the photoresist 230′.

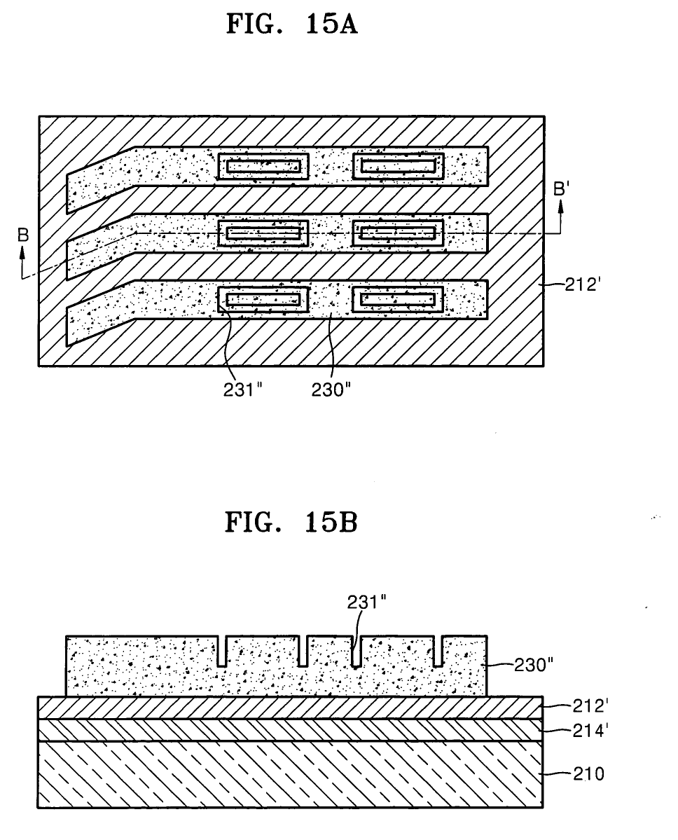

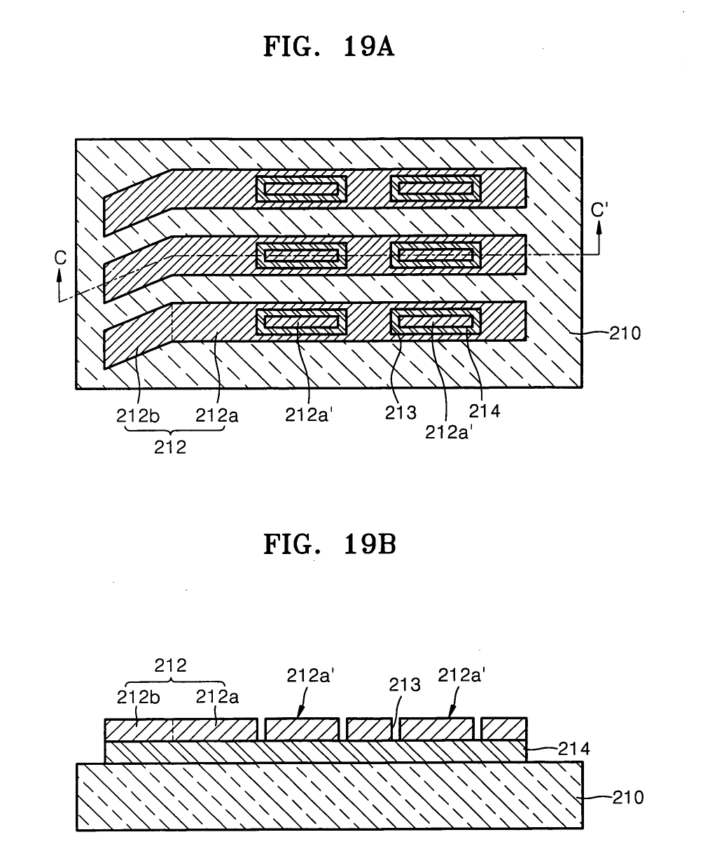

When the exposed photoresist 230′ is developed, a developed photoresist 130″ having a shape as shown in FIGS. 15A and 15B can be obtained. FIG. 15B is a cross-sectional view taken along the line B-B′ of FIG. 15A. More specifically, the photoresist 230′ in the light transmitting region is removed by a developing solution and thus the cathode material layer 212′ located thereunder is exposed. The photoresist 230′ in the light shielding region formed by the first pattern 252a is not removed by the developing solution since the photoresist 230′ is not exposed. The exposed photoresist 230′, that is, the photoresist 230′ located on an upper part of the region that surrounds the emitter forming portions 212a′ of a cathode electrode 212 (see FIGS. 19A and 19B) which will be described later, in the partial light transmitting region formed by the second pattern 252b is removed to a predetermined depth by the developing solution. Accordingly, as shown in FIGS. 15A and 15B, first trenches 231″ having a shape corresponding to a region that surrounds the emitter forming portions 212a′ (see FIGS. 19A and 19B), which will be described later, are formed to a predetermined depth.

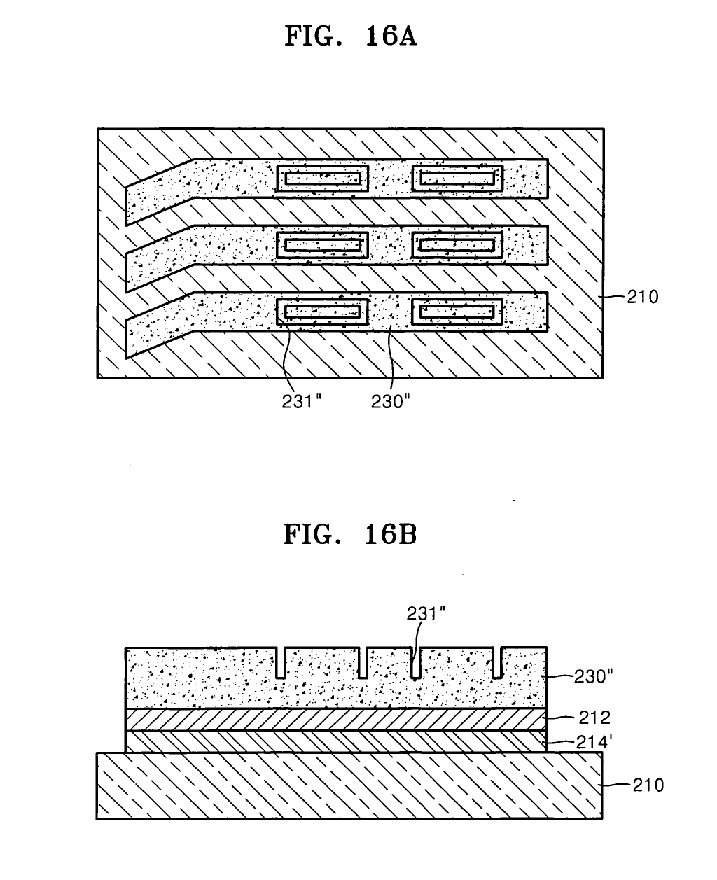

Referring to FIGS. 16A and 16B, a cathode electrode 212 and a resistance layer 214 are formed by sequentially etching the exposed cathode material layer 212′ and the resistance material layer 214′ using the developed photoresist 230″ as an etch mask.

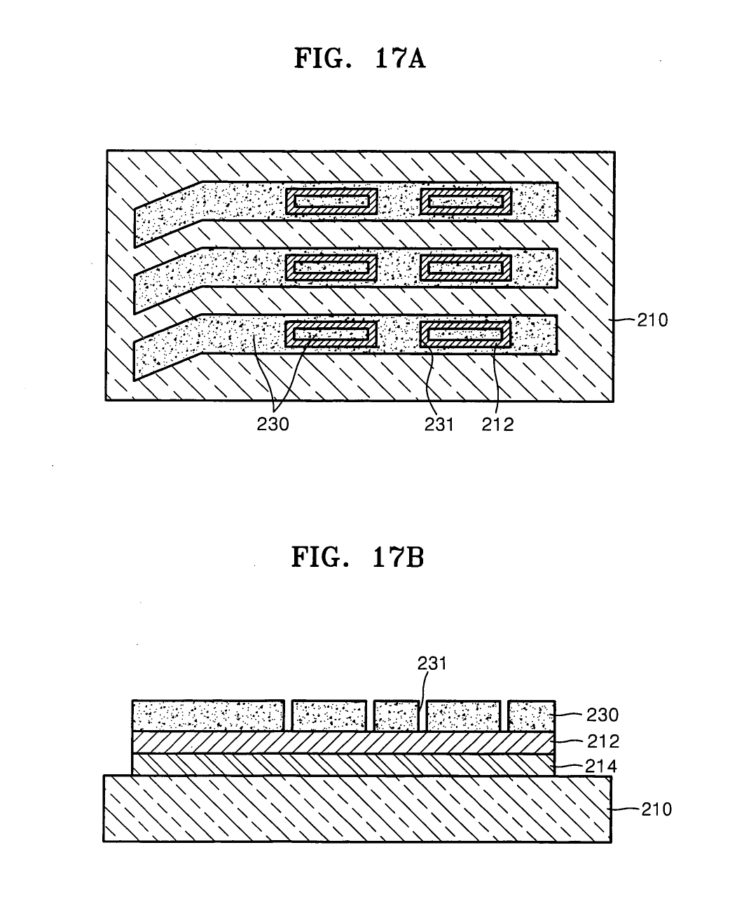

Referring to FIGS. 17A and 17B, a portion of the cathode electrode 212 is exposed by etching the developed photoresist 230″. More specifically, the developed photoresist 230″ is developed using a plasma etching method. Here, the plasma etching method can include Reactive Ion Etching (RIE). In this process, the height of the developed photoresist 230″ is gradually reduced by etching an upper surface of the developed photoresist 230″. The etching of the developed photoresist 230″ is continued until the developed photoresist 230″ in the partial light transmitting region is completely removed and thus the cathode electrode 212, that is, a region that surrounds an emitter forming portions 212a′ (see FIGS. 19A and 19B) of the cathode electrode 212, located under the developed photoresist 230″ is exposed. The developed photoresist 230 in the light shielding region remains at a predetermined height on the cathode electrode 212. As a result, second trenches 231 that expose the region that surrounds the emitter forming portions 212a′ are formed in an etched photoresist 230.

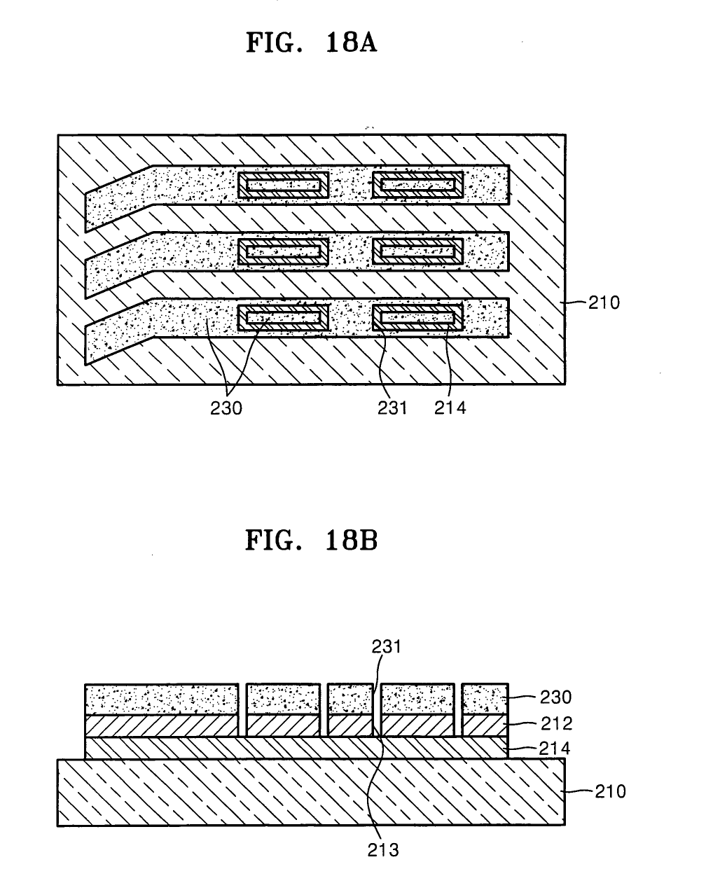

Referring to FIGS. 18A and 18B, the resistance layer 214 located under the cathode electrode 212 is exposed when the exposed cathode electrode 212 is etched using the etched photoresist 230 as an etch mask. Accordingly, third trenches 213 that surround the emitter forming portions 212a′ (see FIGS. 19A and 19B) are formed in the cathode electrode 212. As a result, the emitter-forming portions 212a′ of the cathode electrode 212 become an island shape, i.e., the emitter-forming portions 212a′ are surrounded by the third trenches 213. Referring to FIGS. 19A and 19B, the photoresist 230 remaining on the cathode electrode 212 is removed. FIG. 19B is a cross-sectional view taken along the line C-C′ of FIG. 19A. Reference numeral 212a denotes active regions of the cathode electrode 212, and reference numeral 212b is a pad region of the cathode electrode 212.

Although not shown, the manufacture of an FED is completed when a first insulating layer, a first gate electrode, a second insulating layer, and a second gate electrode are formed on the cathode electrode 212, the resistance layer 214 is formed on the substrate 210 and emitters are formed in the active regions of the cathode electrode 212. In the FED having a double gate structure, the resistance layer 214 ensures uniform intensity of currents emitted from the emitter.

Conventionally, to manufacture an FED having a double gate structure, two photomasks are required to form a cathode electrode and a resistance layer. However, as described above, in the present invention, the number of photomasks can be reduced since the cathode electrode and the resistance layer can be formed using one halftone photomask, thereby simplifying a manufacturing process and reducing costs.

While the present invention has been particularly shown and described with reference to exemplary embodiments thereof, it will be understood by those of ordinary skill in the art that various modifications in form and detail can be made therein without departing from the spirit and scope of the present invention as defined by the following claims.

What is claimed is:

1. A method of manufacturing a Field Emission Display (FED), the method comprising:
sequentially forming a cathode material layer, a resistance material layer, and a photoresist on a substrate;
arranging a half tone photomask on the photoresist, the half tone photomask having a first pattern that shields light and a second pattern that partially transmits light arranged in respective predetermined shapes;
exposing the photoresist to light to develop it;
forming a resistance layer and a cathode electrode by sequentially etching the resistance material layer and the cathode material layer exposed through the developed photoresist;
etching the developed photoresist until the resistance layer located on an upper part of a pad region of the cathode electrode is exposed;
exposing the pad region of the cathode electrode by etching the resistance layer exposed through the etched photoresist; and
removing the photoresist.

2. The FED of claim 1, wherein forming the photoresist comprises forming a positive photoresist.

3. The FED of claim 1, wherein the first pattern is formed corresponding to active regions of the cathode electrode, and the second pattern is formed corresponding to the pad region of the cathode electrode electrically connected to an external power source.

4. The FED of claim 3, wherein the first and second patterns are formed on a transparent substrate.

5. The FED of claim 3, wherein the second pattern is formed to have a light transmittance in a range of 25 to 80%.

6. The FED of claim 3, wherein the photoresist located on an upper part of the pad region of the cathode electrode is exposed and developed to a predetermined depth due to light transmitted through the second pattern.

7. The FED of claim 6, wherein the developed photoresist is etched using a plasma etching method.

8. The FED of claim 7, wherein the plasma etching method comprises Reactive Ion Etching (RIE).

9. A method of manufacturing a Field Emission Display (FED), the method comprising:
sequentially forming a resistance material layer, a cathode material layer, and a photoresist on a substrate;
arranging a half tone photomask on the photoresist, the half tone photomask having a first pattern that shields light and a second pattern that partially transmits light arranged in respective predetermined shapes;
exposing the photoresist to light to develop it;
forming a cathode electrode and a resistance layer by sequentially etching the cathode material layer and the resistance material layer exposed through the developed photoresist;
etching the developed photoresist until a region that surrounds emitter forming portions of the cathode electrode is exposed;
exposing the resistance layer by etching the cathode electrode exposed through the etched photoresist; and
removing the photoresist.

10. The FED of claim 9, wherein forming the photoresist comprises forming a positive photoresist.

11. The FED of claim 9, wherein the first pattern is formed corresponding to the cathode electrode, and the second pattern is formed corresponding to the region that surrounds the emitter forming portion.

12. The FED of claim 11, wherein the first and second patterns are formed on a transparent substrate.

13. The FED of claim 11, wherein the second pattern is formed to have a light transmittance in the range of 25 to 80%.

14. The FED of claim 1, where the photoresist located on an upper part of the region that surrounds the emitter forming portion is exposed and developed to a predetermined depth due to light transmitted through the second pattern.

15. The FED of claim 14, where the developed photoresist is etched using a plasma etching method.

16. The FED of claim 15, where the plasma etching method comprises Reactive Ion Etching (RIE).
